(19) United States
(12) Patent Application Publication
(10) Pub. No.: US 2007/0205432 A1
(43) Pub. Date: Sep. 6, 2007

(54) Heterojunction bipolar transistor and power amplifier using same

(75) Inventor: Toshiya Tsukao, Yamatokoriyama-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/712,507

(22) Filed: Mar. 1, 2007

(30) Foreign Application Priority Data
Mar. 6, 2006 (JP) 2006-060058

(51) Int. Cl. H01L 29/732

(52) U.S. Cl. 257/183

(57) ABSTRACT

In order to lay out a power amplifier heterojunction bipolar transistor capable of large power output in a small area, the subject invention provides a heterojunction bipolar transistor constituted of a plurality of transistor components arranged on a sub-collector layer, collector layers of said transistor components being separated one another, said transistor components being arranged in a line in a longitudinal direction of an emitter. The subject invention also provides a multi-finger type heterojunction bipolar transistor using the heterojunction bipolar transistor as a unit transistor.

This Nonprovisional application claims priority under 35 U.S.C. § 119(a) on Patent Application No. 2006/060058 filed in Japan on Mar. 6, 2006, the entire contents of which are hereby incorporated by reference.

### FIELD OF THE INVENTION

The present invention relates to a heterojunction bioplar transistor which is useful for constructing a transmission power amplifier for a high-frequency radio communications system, such as mobile phones or wireless LAN, and a power amplifier using the heterojunction bipolar transistor.

### BACKGROUND OF THE INVENTION

A general transmission power amplifier in a high-frequency system for handling several hundreds MHz to more than 1 GHz, such as mobile phones or wireless LAN, is made of a heterojunction bipolar transistor (HBT, hereinafter) as an amplifying element. A general HBT is mainly formed from a compound semiconductor such as GaAs. The HBT is a bipolar transistor whose emitter is made of a semiconductor material which has a greater bandgap than the base material, and the bandgap difference causes a potential difference in the base/emitter junction, which serves as an injection barrier to the emitter with respect to the holes in the base. As a result, the recombination current due to the holes is suppressed, and a high current gain is obtained. Further, this effect allows an increase in doping concentration of the base with the same gain, which decreases base resistance. The resulting transistor is capable of high-speed operation. AlGaAs and InGaP emitter are examples for a GaAs base.

The transmission power amplifier serves as a Microwave Monolithic IC (MMIC, hereafter), which is provided on the same semiconductor substrate as that of HBT. The MMIC thereon integrates a bias circuit, a matching circuit etc. for operating HBT properly, and these circuits are made of various wires, passive elements such as condenser or inductor.

FIG. 13 shows a structure example of power amplifier MMIC. In the figure, “IN” denotes input terminal, “OUT” denotes output terminal, “Vbb” denotes base power supply terminal, “Vc1” denotes collector power supply terminal, which indicate interfaces between the MMIC and an external circuit. The example of FIG. 13 is a two-stage amplifier in which HBT201 and HBT202 carry out amplification of the first and second stages (output-stage), respectively. The matching circuit 204 is a circuit constituted of a passive element, and serves to make impedance matching between a signal source connected to an input terminal IN and a base input of HBT201. Further, the bias circuit 205 serves to generate a base bias of HBT201 in the first stage. Similarly, to match impedances of the output of the first stage and the input of the second stage, a matching circuit 207 is provided between the collector of HBT201 and the base of HBT202. A bias circuit 208 serves to generate a base bias of HBT202. In a transmission power amplifier, a HBT with a large-sized emitter is used for the output stage HBT202 because the output stage needs to have a large current driving capability to ensure the required degree of transmission power.

A vertical npn-type bipolar transistor is one of typical HBTs made of a compound semiconductor. The vertical npn-type bipolar transistor is formed by layering a collector layer, a base layer, and an emitter layer on a semiconductor substrate by epitaxial growth, and dividing the layers by mesa-etching. FIG. 8 shows a plan view of HBT, FIG. 9 shows a cross-sectional structure view of a broken line section of FIG. 8, denoted by a line A-A′.

A high-frequency power amplifier HBT generally has a spindly emitter region as with the emitter region 113 shown in FIG. 8. Along each of two longitudinal sides of the emitter region 113, a spindly base electrode 122 is formed on a base region 112. The collector electrode 121 is formed on a collector region 111 of the base region along the longitudinal side.

A bipolar transistor has such a tendency that when the transistor is driven by a large current, the voltage decrease due to spreading resistance from the base electrode to the emitter becomes significant, and therefore only a part of the emitter region (periphery of emitter) near the base electrode is properly driven. This phenomenon is called an edge effect. In consideration of this effect, a power amplifier transistor assuming large current driving uses a spindly emitter with a long periphery. A typical size of the shorter-length side is 2 μm to 6 μm. Further, to effectively operate the emitter region, a base electrode is generally provided along each of the longitudinal sides of emitter region. Further, as a requirement for high-frequency operation, it is necessary to keep the base resistance and the base-collector capacitance small. Therefore, the base electrode is provided to be very close to the emitter region, and is formed in a spindly shape to make the area of the base region for regulating the base-collector capacitance as small as possible. The size is typically 0.5 μm to 1.5 μm.

In the base electrode 122 shown in FIG. 8, the two electrodes disposed along the two longitudinal sides of the emitter region 113 are tied together at one end to form a spindly rectangle with an open side. The base electrode is made relatively small, and therefore has a difficulty in conducting plural electrodes with a drawing wire which is described later, and therefore a thick binding section is provided to conduct the electrode, and also to conduction into a drawing wire 142.

In this example, the collector electrode 121 is also made as a rectangle with an open side. This shape of collector electrode 121 is large enough to surround the base region 112, and therefore decreases the contact resistance of electrode, thereby reducing the collector resistance.

The following explains further detailed structure also with reference to the cross-sectional view of FIG. 9. On a semi-insulative semiconductor substrate 101, a buffer layer 102, a sub-collector layer 103, a collector layer 104, a base layer 105, and an emitter layer 106 are formed in this order by epitaxial growth. The buffer layer 102 is a high-resistance layer which is formed first as a base of lamination. As the base, the buffer layer 102 serves to stabilize the qualities of the layers stacked thereon, and does not directly contribute to the transistor operation. The sub-collector layer 103 is a n-type layer having been highly densely doped, and is made to form a low contact resistance collector electrode 121. The collector layer 104 is a low concentration n-type layer, and the base layer 105 is a high concentration p-type layer, and an emitter layer 106 is made of a n-type wide bandgap material. In the case of a HBT with a InGaP emitter layer, the semi-insulative substrate 101, the buffer layer 102, the sub-collector layer 103, the collector layer 104, and the base layer 105 are made of GaAs, and the emitter layer 106 is made of InGaP. Note that, a practical HBT has more complicated structure including a contact layer for the emitter electrode or layers for interface control with the epitaxial layer and for reliability assurance, but basic transistor operating is performed schematically with the following structure.

The respective layers are etched either by wet-etching or dry-etching excluding a predetermined area (mesa-etching), and the emitter region, the base region, and the collector region are formed. On these regions, the emitter electrode 123, the base electrode 122, and the collector electrode 121 are respectively formed. The electrodes are then connected to layers corresponding to the respective regions. Thereafter, to cover the whole body including the electrodes, an insulative film (not shown), such as a SiN film, SiO₂ film or a polyimide film is formed. The electrodes are drawn outward by the wiring electrodes connected via the contact hole of the insulative film (not shown) covering the electrodes, and are conducted to external circuit elements.

Referring back to FIG. 8, the collector electrode 121 is connected to a drawing wire 141 via a contact hole 131, drawn toward the longitudinal side of electrode. The base electrode 122 is connected to a drawing wire 142 via a contact hole 132, drawn toward the longitudinal side of electrode in the opposite direction to the collector electrode. The emitter electrode 123 is connected to a wide drawing wire 155, whose width is substantially identical to the electrode longitudinal length via a contact hole 133, drawn to both sides by crossing the longitudinal side of the transistor.

To be driven at high efficiency, a power amplifier transistor generally uses a large emitter current. Therefore the resistance of emitter wire greatly affects voltage decrease. As with the foregoing example, provision of wide drawing wire entirely covering the electrodes from right above the emitter electrode gives an effect of decreasing influence of the resistance in the longitudinal direction of the emitter, even in a spindly emitter. A transistor constituting a power amplifier circuit is generally driven by emitter earthing. Such a wide drawing wire gives an effect of reducing earthing inductance, which becomes a defect in high-frequency driving, and also gives an advantage of assurance of desirable heat liberation to the heatsink through the earth terminal. This structure can be found in Japanese Laid-Open Patent Publication Tokukai 2002-246587, for example.

With reference to FIGS. 10 and 11, the following explains another prior art example of HBT having a plurality of emitters. FIG. 10 is a plan view of a HBT, and FIG. 11 is a cross-sectional view, taken along the line B, B′ of FIG. 10. In the figure, materials having the equivalent functions as those shown in FIGS. 8 and 9 will be given the same reference symbols, and explanation thereof will be omitted here.

The prior art example shown in FIGS. 10 and 11 has a structure in which two emitter regions 115 and 116 are formed on the base region 112. More specifically, on the base region 112 made of the collector layer 104 and the base layer 105 formed by mesa-etching, the two emitter regions 115 and 116 are formed respectively from two emitter layers 106 also formed by mesa-etching. This structure can be found in Japanese Laid-Open Patent Publication Tokukai 2002-076014, for example. The respective emitter regions 115 and 116 includes emitter electrodes 125 and 126, respectively, and these electrodes are drawn outward by connecting into a single drawing wire 155, respectively via contact holes 135 and 136. To decrease the base resistance, the base electrode 122 has three fingers and the two emitter regions 115 and 116 are caught between these fingers.

With this structure having a plurality of emitters on a single base region, it becomes possible to obtain a relatively large emitter area even in the spindly shape. This structure also gives an effect of suppressing an increase in base region area ratio (increase in capacitance between base-collector) along with decrease in width of emitter. This structure is therefore useful for a transistor driven by a large current.

Further, in this conventional art, the contact hole 131 is formed on the entire collector electrode 121, and the drawing wire 141 covers the collector electrode 121. This structure has an effect of reducing the resistance of contact electrode, and therefore is further useful for large current driving.

Note that, the number of emitters for a single base region is not limited, and more than two emitters may be used depending on application or process.

In the conventional transistors shown in FIGS. 8 to 11, the element division is made by dividing the sub-collector layer 103 by mesa-etching. However, the element division in a semiconductor substrate can also be done by ion injection. FIG. 12 is a cross-sectional view showing element division by ion injection. For ease of explanation, materials having the equivalent functions as those shown in FIG. 9 will be given the same reference symbols, and explanation thereof will be omitted here.

The region 108 in the figure denotes a division region given a high resistance by injection of ion such as hydrogen, oxygen, or boron. The region 108 is surrounding the transistor, thereby dividing elements. This structure can be found in Japanese Laid-Open Patent Publication Tokukaihei 3-190244, or in Japanese Laid-Open Patent Publication Tokukaihei 10-242160, for example.

As it handles a large current, the power amplifier transistor requires a large emitter area. For this reason a general power amplifier transistor is realized by a multi-finger type HBT constituted of a plurality of the described HBTs are used as unit transistors, and are arranged in parallel on a semiconductor substrate. As one example of this multi-finger type HBT, a HBT with the unit transistors arranged in a line is disclosed in Japanese Laid-Open Patent Publication Tokukai 2002-076014 and in Japanese Laid-Open Patent Publication Tokukaihei 6-104275. FIG. 6 shows an example of this layout. This layout in which the unit transistors are arranged in a line is hereinafter referred to as an inline layout. The size of transistor is expressed by a length, which denotes the length of emitter electrode, and by a width, which denotes the same in the short-length side direction. As to the direction, the longitudinal direction of the unit transistor is referred to as finger direction, and the short-length side direction is referred to as alignment direction.

The unit transistor 50 shown by a broken line in FIG. 6 has the same arrangement as the HBT shown in FIGS. 10 and 11 in which two emitter regions are formed on a separated single base region. The unit transistors 50 are arranged in a line in the finger direction, and the base electrode and the collector electrode of each unit transistor 50 are connected in parallel respectively by the drawing wires 15 and 14, and are respectively drawn toward opposite ends of the finger direction. The drawing wires 15 and 14 are arranged to be connected to an external circuit outside the figure via connecting sections 25 and 24. The emitter electrode is connected to a drawing wire 16 which extends in the alignment direction right above the aligned transistors. Each end of the drawing wire 16 of the emitter electrode is connected to a via hole 26, which penetrates through the semiconductor substrate and is connected to an earth electrode provided on the rear surface of the semiconductor substrate.

With the via holes 26 provided on the both ends of the aligned transistors, the length of wire between the emitter and the ground potential can be reduced. Therefore, it is possible to keep the grounding inductor small which degrades power gain or linearity in high-frequency amplification. Further, the drawing wire 16 of the emitter electrode also serves as a heat liberation path to a heatsink which is in contact with the earth electrode on the rear surface of the semiconductor substrate via the via hole 26, thereby stabilizing the operation of transistor.

In the multi-finger type HBT in the inline layout, the wire arrangements of signal input wire (=drawing wire 15 of base electrode) and signal output wire (=drawing wire 14 of collector electrode) of the power amplifier transistor are significantly simple, and the reduction of wire length between input and output is possible, which gives an effect of reduction in loss of signal transmission, and reduction in layout area.

Alternatively, the multi-finger type HBTs may be arranged in plural finger lines in matrix, as disclosed in Japanese Laid-Open Patent Publication Tokukai 2002-016078 or Japanese Laid-Open Patent Publication Tokukai 2001-237319. The following explains an example of the matrix layout from Japanese Laid-Open Patent Publication Tokukai 2001-237319, which is shown in FIG. 7. Note that, in FIG. 7, materials having the equivalent functions as those shown in FIG. 6 will be given the same reference symbols, and explanation thereof will be omitted here.

Each finger line 52 is constituted of a plurality of unit transistors 50, and the base electrode and the collector electrode of each unit transistor are respectively connected to the drawing wires 15 and 14 in parallel. Further, the drawing wires 15 and 14 for each finger line is tied together by the connecting sections 25 and 24, connected to an external circuit (not shown). The emitter electrode is connected to the drawing wire 16 extending right above the unit transistors 50, and the drawing wire 16 is connected to the via hole 26 in an end to be grounded.

Such a matrix layout is used for a multi-finger type HBT constituted of a relatively large number of unit transistors having small emitter areas. With the use of the unit transistor having a small emitter area, current unevenness does not easily occur in each unit transistor even with large current density, and therefore it gives an effect that the output power securely corresponds to the number of transistors. Further, since the unit transistor has a relatively small emitter area, it is possible to obtain the required output power by providing an appropriate number of unit transistors. Further, since a small transistor can more easily carry out parameter extract for modeling with high accuracy than a large transistor, the use of the small transistor more easily ensures consistency with simulation in the designing process.

However, the multi-finger type HBT laid out in matrix includes many unit transistors which all need to be connected one another, which makes the wire arrangement more complicated. For this reason a larger wiring area is required, which means a larger chip area is required for the power amplifier MMIC mounting the HBT. Therefore, when reduction in chip area is more important factor in designing, a multi-finger type HBT with inline layout is more useful.

In the case of a multi-finger type HBT with inline layout shown in FIG. 6, an increase in output power according to the spec demand can be attained by an increase in emitter area of the multi-finger type HBT, which is made by an increase in finger number in alignment direction, or an increase in emitter length in the unit transistor.

However, an increase in finger number also increases the width of the entire multi-finger type HBT. Therefore, when mounted to the MMIC, the HBT has a significantly large chip size in width direction, which makes it difficult to arrange the layout with desirable area efficiency. Further, since in this layout the transistor provision area extends in the alignment direction, variation in characteristic or operation temperature distribution among the unit transistors increases. Consequently, unevenness of operation current between the fingers (so-called “hot spot”) more easily occurs.

On the other hand, an increase in emitter length of the unit transistor causes the following problem. With the use of the above-mentioned transistor shown in FIGS. 8 to 11 in which a sufficiently thick drawing wire is formed right above the emitter, it is possible to minimize the influence of wiring resistance in emitter longitudinal direction which causes characteristic deterioration along with an increase in emitter length. This ensures desired level of characteristic even in a transistor with a relatively long emitter length. However, according to some test results, there is a limitation for the emitter length for ensuring even operation to a certain extent. The characteristic decreases when the length falls out of a certain range. FIG. 14 is a graph showing a result of experimental measurement of saturated output power with respect to some different emitter lengths of the unit transistor, with a constant emitter area. This graph shows that the saturated output power rapidly decreases when an emitter length falls out of 50 μm.

In a transistor with such a layout, the characteristic deterioration along with the increase in emitter length is assumed to be mainly derived from extension of base electrode. For example, in FIG. 10, a wide drawing wire 155 is formed right above the emitter electrodes 125 and 126, thereby ensuring current uniformity in the length direction; on the other hand, the drawing wire 142 of the base electrode 122 is drawn from the connecting section which is made up of three ends of base electrodes tied together via a contact hole 132. More specifically, the potential of the base electrode 122 is supplied only from one end of the finger direction, and therefore easily affected by the resistance in the direction of electrode length.

As described above, a transistor assuming high-frequency driving is required to have a small size base electrode and therefore has the foregoing layout. A base current is generally about a hundred times smaller than the emitter current, and therefore the influence by the electrode resistance of base electrode is smaller than that of emitter electrode. Therefore, the characteristic deterioration due to the resistance of base electrode is small if the emitter length does not greatly exceed 50 μm. However, when the length exceeds 50 μm, the influence of potential decrease due to the resistance of base electrode becomes significant, which makes the operation of transistor in finger direction uneven, thus decreasing the saturated output power.

Because of such a phenomenon, there is a difficulty in ensuring sufficient output power corresponding to the increase in emitter area, even with an increase in emitter length of the unit transistor constituting the multi-finger type HBT. Therefore, it is indispensable to increase the finger number when a multi-finger type HBT requiring large output power is formed with the inline layout. This has been holding back creation of a practical multi-finger type HBT securing advantage of inline layout, that is, assurance of desirable characteristic and reduced chip area at the same time.

### SUMMARY OF THE INVENTION

The present invention provides a heterojunction bipolar transistor comprising a plurality of transistor components on a sub-collector layer, collector layers of said transistor components being separated one another, said transistor components being arranged in a line in a longitudinal direction of an emitter.

This invention enables formation of a plurality of transistor components, each of which has a separate collector layer on a sub-collector layer. With this arrangement, the problem of significant increase in emitter length of transistor in providing a sufficient emitter area for obtaining a desired output may be solved by such division of transistor components. On this account, the required emitter area is ensured without increasing the effective emitter length which affects characteristic deterioration. Along with this, the plurality of transistor components are arranged in a line on a single separate sub-collector layer in the longitudinal direction of the emitter; and therefore, though the increase in number of transistor components with the increase in emitter area causes an increase in transistor length, it does not cause a significant change in transistor width.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a plan view of a HBT according to the first embodiment of the present invention.

FIG. 2 is a plan view of a multi-finger type HBT according to the first embodiment of the present invention.

FIG. 3 is a plan view of a HBT according to the second embodiment of the present invention.

FIG. 4 is a plan view of a multi-finger type HBT according to the third embodiment of the present invention.

FIG. 5 is a circuit diagram for explaining the third embodiment of the present invention.

FIG. 6 is a plan view of a conventional multi-finger type HBT.

FIG. 7 is a plan view of a conventional multi-finger type HBT.

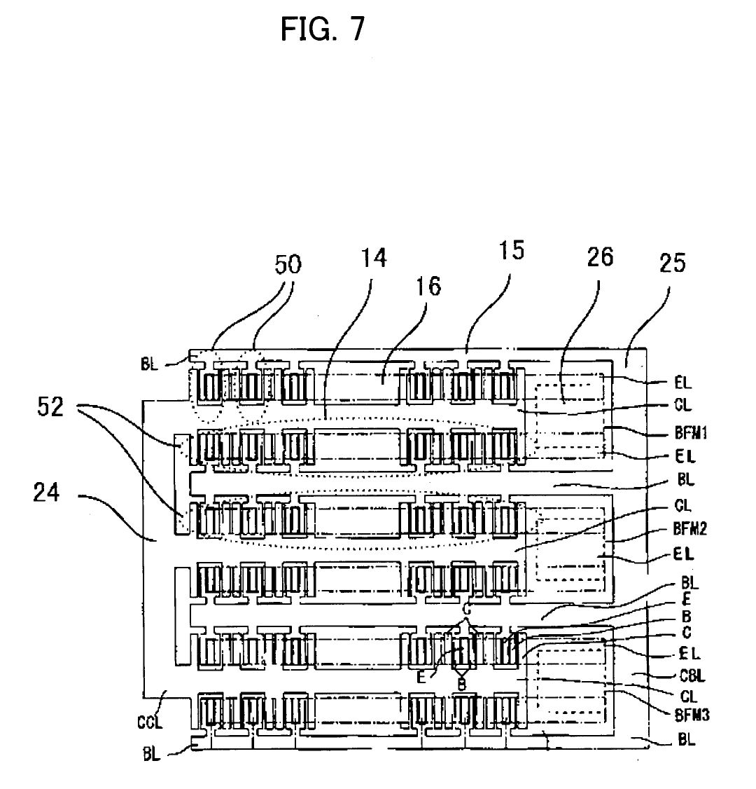

FIG. 8 is a plan view of a conventional HBT.

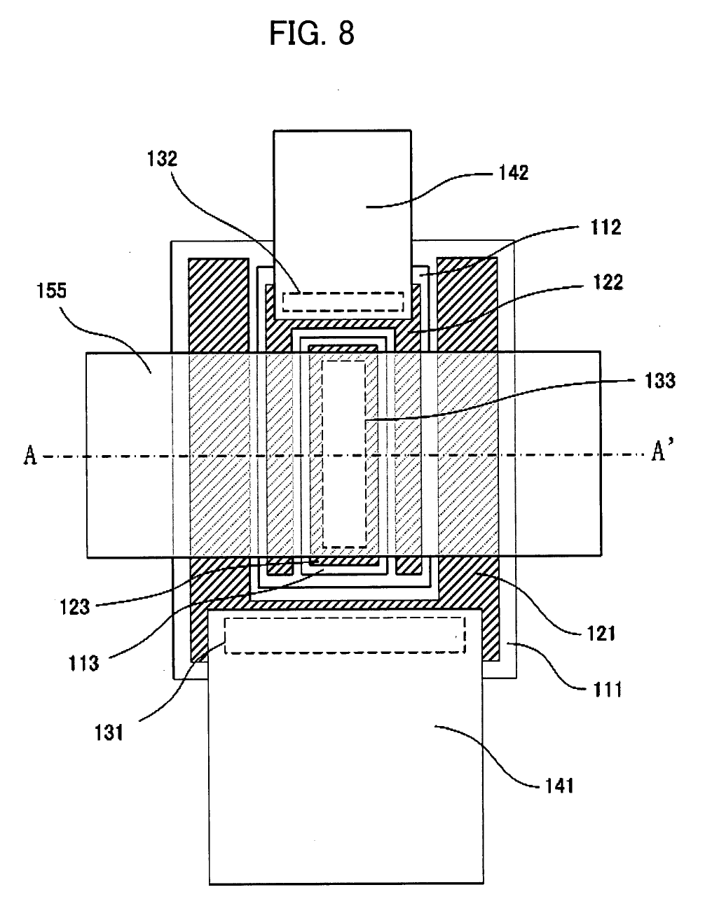

FIG. 9 is a cross-sectional view of the HBT shown in FIG. 8.

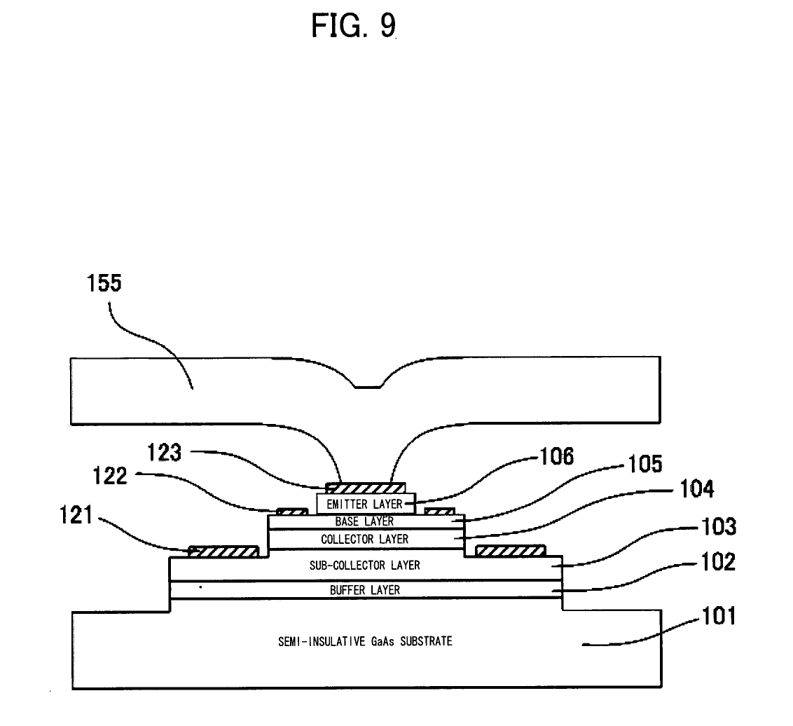

FIG. 10 is a plan view of a conventional HBT.

FIG. 11 is a cross-sectional view of the HBT shown in FIG. 10.

FIG. 12 is a cross-sectional view of a conventional HBT.

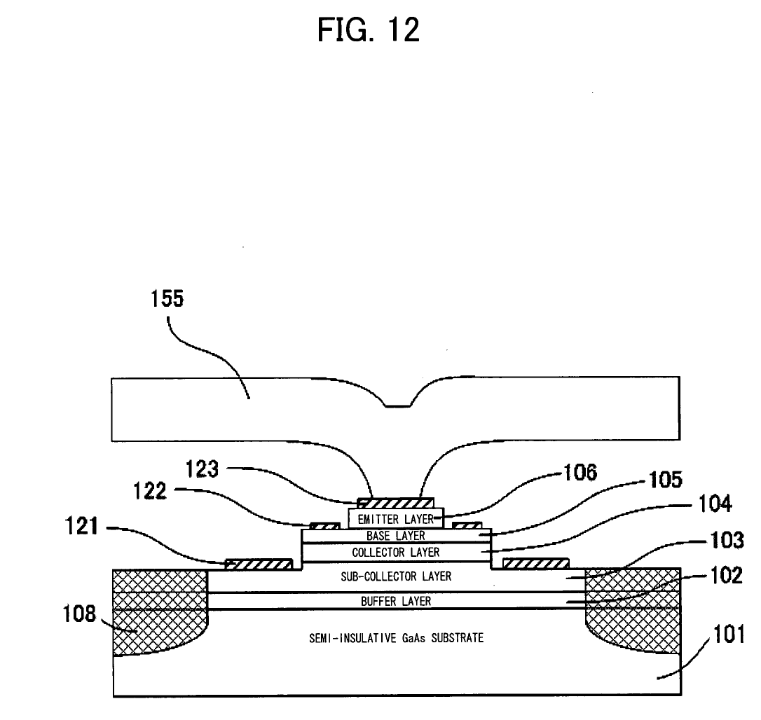

FIG. 13 is a circuit diagram of a conventional power amplifier MMIC.

FIG. 14 is a graph showing a characteristic of a conventional HBT.

### DESCRIPTION OF THE EMBODIMENTS

### First Embodiment

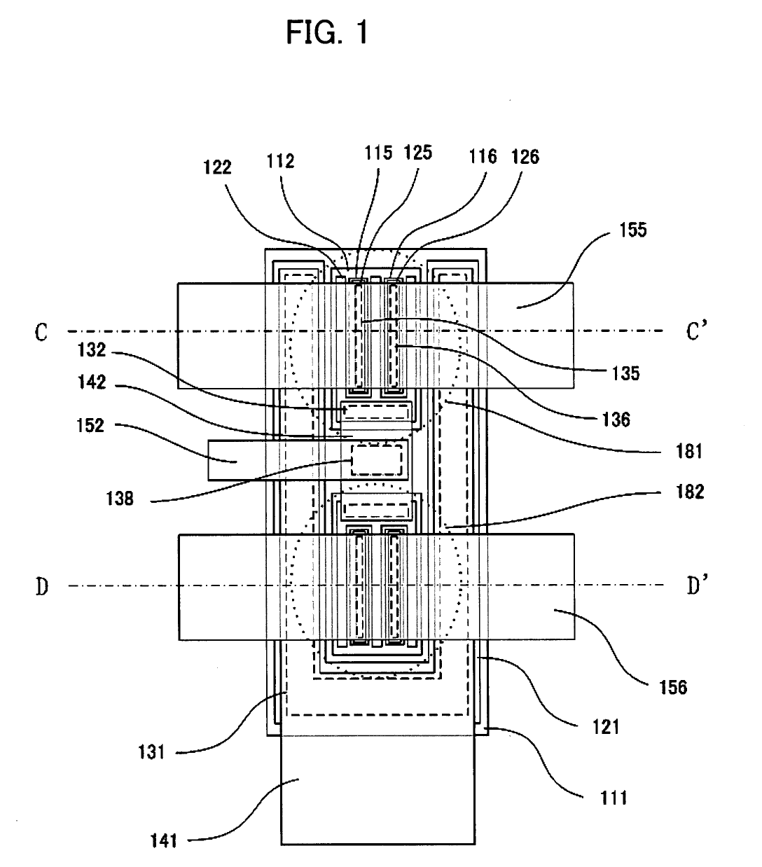

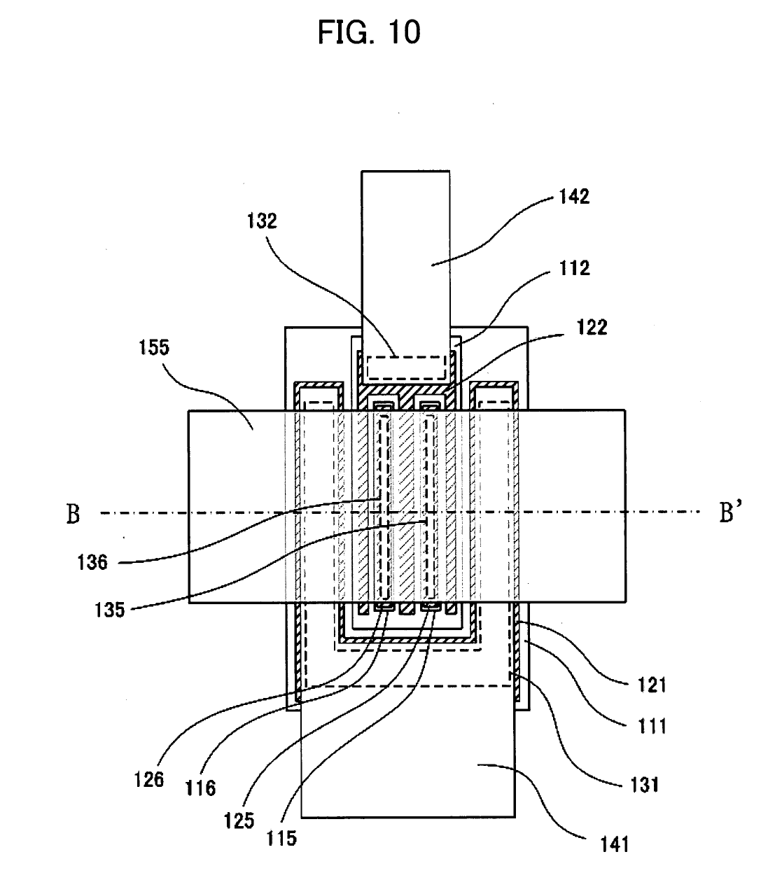

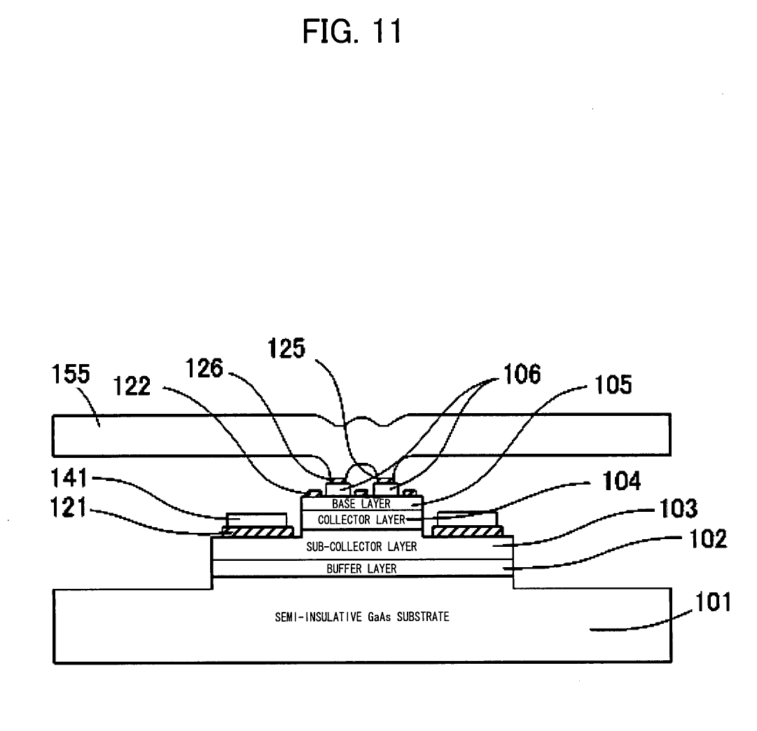

FIG. 1 is a plan view of a transistor, showing a HBT according to the first embodiment of the present invention. The present embodiment is an application example to a conventional HBT explained in the section of “background art” with reference to FIGS. 10 and 11, in which two emitters are formed on a single base region. For ease of explanation, materials having the equivalent functions as those shown in FIGS. 10 and 11 will be given the same reference symbols, and explanation thereof will be omitted here. Further, since the transistor components 181 and 182 are identical as describes below, only a reference numeral 181 is used for the transistor component, and a component corresponding to the transistor component 182 is also expressed by the same number, for ease of explanation with FIG. 1.

In the present embodiment, two transistor components 181 and 182 (denoted by a broken line) are formed on a single collector region 111, and these transistor components are arranged in a line in the finger direction. The transistor components 181 and 182 are identical in structure, which is the same as that of a conventional transistor shown in FIG. 10. That is, the cross-sections taken along the lines C-C′ and D-D′ in the figure are the same as the cross-section of a conventional transistor shown in FIG. 11. The transistor components 181 and 182 shares a sub-collector layer, that is the collector region 111, which further incorporates two collector layers 104 formed in the orthogonal direction to the lines C-C′ and D-D′ (in FIG. 1, they are overlapped with the base region 112 (described later)). In this way, the two transistor components 181 and 182 are separated.

The collector electrode 121 formed as a rectangle with an open side is formed on a single collector region 111 around the base regions 112 of the two transistor component 181 and 182. The collector electrode 121 is connected to a drawing wire 141 via a contact hole 131. At this time, the contact hole 131 is formed substantially on the entire surface of the collector electrode 121, and the drawing wire 141 is so formed as to cover substantially the entire part of the collector electrode 121. In the embodiments of the present invention, the collector electrode is formed around the whole transistor components arranged in line in the finger direction, and therefore has a longer length. Since the drawing wire 141 covers the collector electrode 121, the resistance of this long electrode can be reduced. This structure is therefore useful for the present embodiment.

The two transistor components 181 and 182 are formed so that their base electrodes are drawn to opposite directions, and the base electrodes 122 are connected to the first drawing wire 142 of the base electrode via the contact holes 132. With this arrangement of sharing the drawing wire of the base electrode, the size of transistor can be reduced. Further, the first drawing wire 142 of the base electrode is connected via the contact hole 138 to the second drawing wire 152 of the base electrode formed thereabove via an insulative film (not shown), drawn transversely with respect to the longitudinal side of the transistor. This is because the base electrode of the second drawing wire 152 is drawn transversely with respect to the collector electrode, and therefore it is necessary to use a wire above the drawing wire 141 of the collector electrode. The first drawing wire 142 of the base electrode is formed from the wires by which the drawing wire 141 of the collector electrode is formed.

The emitter electrodes 125 and 126 formed on the two emitter regions 115 and 116 of the transistor components 181 are connected to a drawing wire 155, drawn transversely with respect to the longitudinal side of the transistor. Similarly, the emitter electrodes 125 and 126 of the transistor component 182 are drawn to be connected to the drawing wires 156. The drawing wires 155 and 156 of the emitter electrode are drawn transversely with respect to the drawing wire 141 of the collector electrode, and therefore are drawn by a wire in the upper layer, as with the second drawing wire 152 of the base electrode. The drawing wires 155 and 156 of the emitter electrode are connected to each other via a wire not shown in the figure.

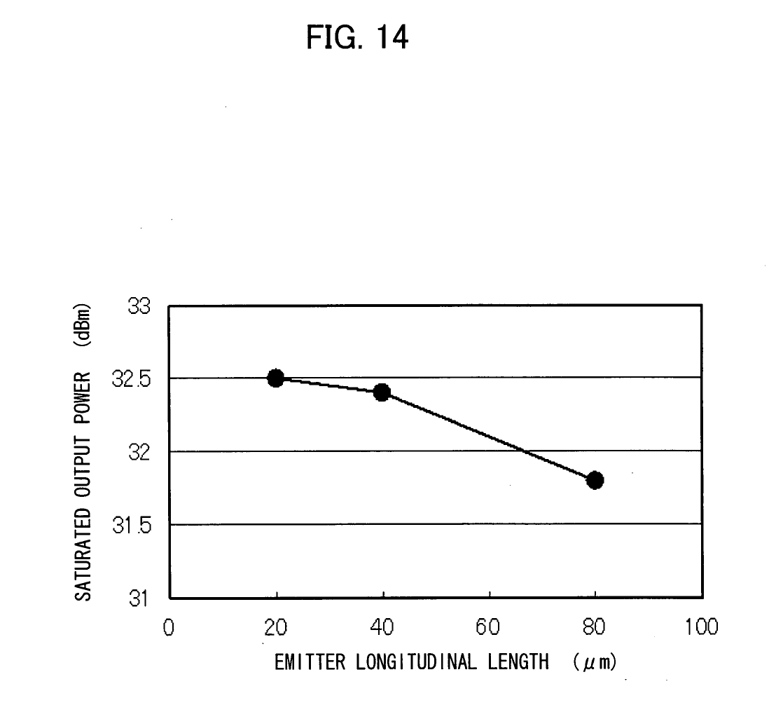

The transistor shown in FIG. 1 has two transistor components 181 and 182 on a single collector region 111. The base of one of the two transistor components is connected to the base of the other transistor, and the emitter of one of the two transistor components is also connected to the emitter of the other transistor. The two transistor components thus form a single transistor. With this arrangement in which the emitter area is broken into two transistor components, a large emitter area may be provided as required. It is therefore not necessary to increase the effective emitter length, which affects degradation of characteristic, according to the relationship of FIG. 14. More specifically, it is possible to keep the small effective emitter length, and the transistor is not likely to have a problem of uneven driving. On this account the transistor ensures desirable characteristic. Further, to evenly operate the plural transistor components, it is preferable to form the transistor components into the same size.

The two transistor components 181 and 182 are arranged in a line in the finger direction on a single collector region 111. With this configuration, it is possible to form the transistor substantially in the same width as that of a single transistor component. This effect becomes particularly advantageous in composing the following multi-finger type HBT.

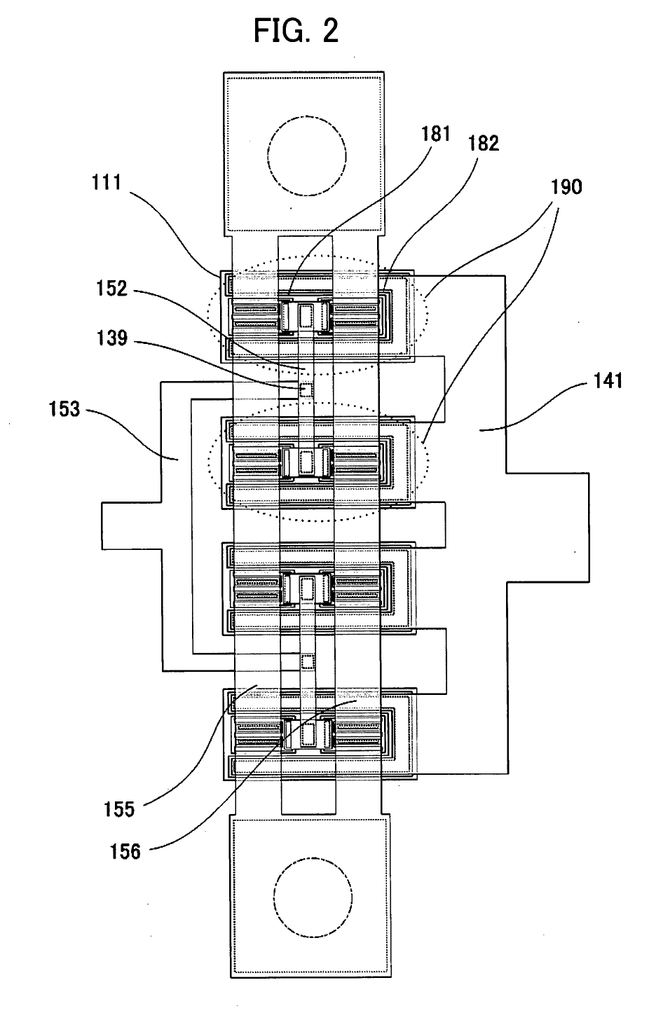

FIG. 2 is a plan view showing an example of multi-finger type HBT composed by arranging a plurality of unit HBTs shown in FIG. 1 in the inline layout. In this example, 4 unit transistors are provided but the number of transistors is not particularly limited, and may of course be determined arbitrarily.

The unit transistor 190 shown in FIG. 2 by a broken line has the same structure as that of the HBT of FIG. 1 in which two transistor components 181 and 182 are formed on the single collector region 111. The 4 unit transistors 190 are arranged in a line in the short-length side direction of the emitter region, aligned in terms of the finger direction. The collector electrode of the unit transistor 190 is drawn by the drawing wire 141 toward one side of the finger direction, lead to the connecting section to be conducted with a circuit outside the figure. The emitter electrode is connected to the drawing wires 155 and 156 which run transversely right above the transistor components. The drawing wires 155 and 156 are grounded through via holes on the both sides of the finger alignment.

The base electrode is drawn transversely with respect to the finger direction of the unit transistors 190. In the embodiment shown in FIG. 2, a group of two transistors is made among the unit transistors constituting the multi-finger type HBT. The drawing wires of the pair of the unit transistors are drawn to opposite directions, and are connected to each other by the drawing wire 152. The drawing wires 152 of the respective base electrodes of the pair of unit transistors are connected to each other via the contact hole 139 which is formed below through an insulative film (not shown), lead to the connecting section to be conducted with a circuit outside the figure. With this wiring arrangement, all of the unit transistors have the same-length input signal paths to the base electrode, so that the signals supplied to the respective transistors become uniform in phase, and efficient driving of transistor can be more easily ensured.

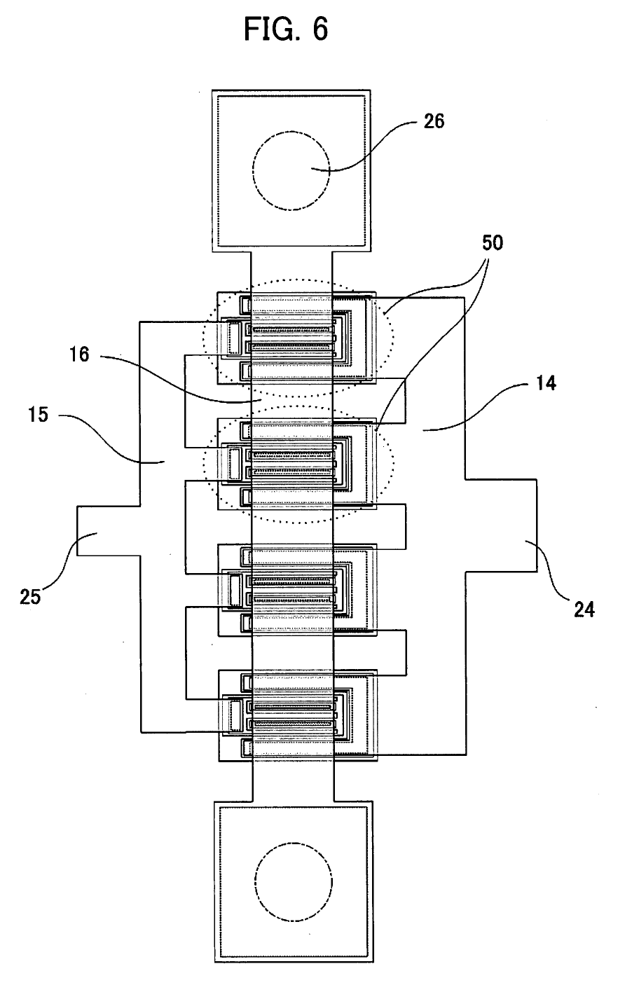

As described, two transistor components are formed on a single collector region. With this configuration of transistor components, a multi-finger type HBT in which unit HBTs are aligned in the finger direction is formed. With this structure of the present embodiment, a larger emitter area can be provided to the unit transistor while ensuring the desired characteristic. In this way, a multi-finger type HBT capable of large output can be realized without increasing the number of fingers. Further, since the unit transistor of the present embodiment has the same width as that of the multi-finger type HBT of FIG. 6 having the conventional layout, the similar inline layout can be realized with a smaller area, that is, without greatly increasing the length of the finger alignment direction.

### Second Embodiment

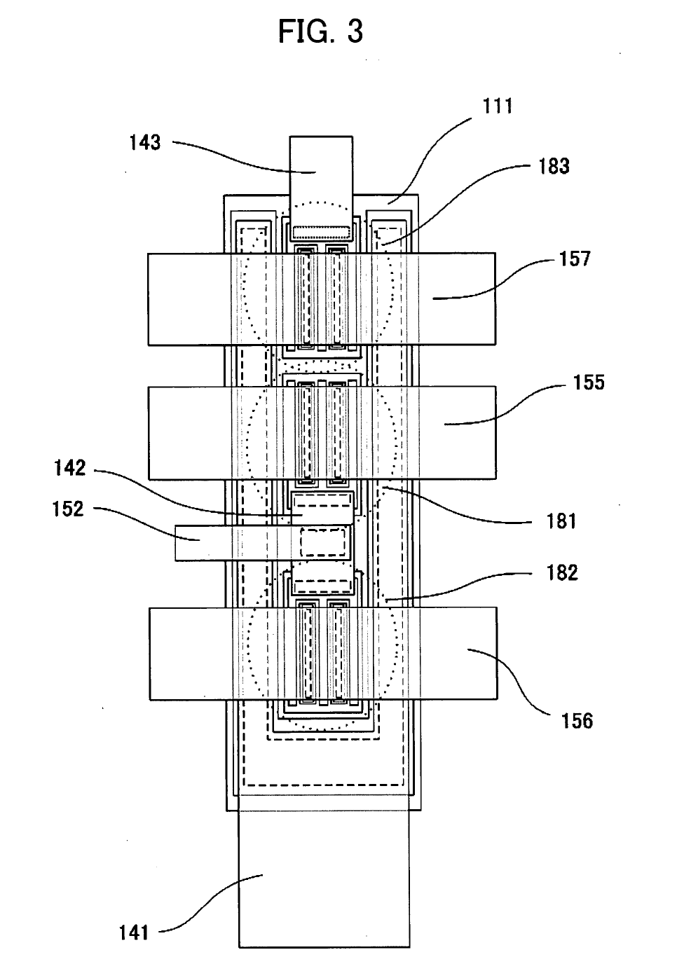

FIG. 3 shows a HBT including 3 transistor components according to the second embodiment of the present invention. The HBT of the present invention are mostly constituted of the same componential members as those of the HBT of the first embodiment shown in FIG. 1, and therefore materials having the equivalent functions as those of FIG. 1 will be given the same reference symbols, and explanation thereof will be omitted here. Also, for ease of explanation, some reference numerals are omitted from the figure.

The HBT according to the present invention is constituted of plural unit transistors 190, each of which is constituted of three transistor components 181, 182 and 183 with separate collector layers on a single separate collector region 111. The respective transistor components are identical in structure to the transistor components 181 and 182 of the first embodiment of FIG. 1 having the two emitter fingers. The present embodiment includes one more transistor component on the collector region 111. These 3 transistor components 181, 182 and 183 are arranged in a line in the finger direction. With this structure of the present embodiment having a larger number of transistor components, a larger emitter area can be realized.

Among 3 transistor components, the adjacent two transistor components 181 and 182 are disposed so that their base electrodes are drawn in opposite directions. Their base electrodes are connected to each other by the drawing wire 142, and the drawing wire 142 is connected to the drawing wire 152 on the upper layer, drawn transversely with respect to the longitudinal side of the transistor. The base electrode of the remaining transistor component, the transistor component 183, is connected to the drawing wire 143, drawn in the longitudinal direction but oppositely to the drawing wire 141 of the collector electrode. These drawing wires of the base electrodes are connected to each other via a wire outside the figure.

The emitter electrodes are connected to the drawing wires 155, 156 and 157 right above the transistor components 181, 182 and 183, drawn transversely with respect to the longitudinal side of the transistor, before being connected to each other via a wire outside the figure.

The number of transistor components may be arbitrarily increased in this manner according to the desired size of emitter area. If the increase in length of collector electrode causes an unwanted increase in resistance, an increase in width of collector electrode will solve the problem.

By forming a multi-finger type HBT with the HBTs of the present embodiment, it is possible to lay out a multi-finger type HBT with a large emitter area, without greatly increasing the length of the finger alignment direction.

### Third Embodiment

In operating a multi-finger type HBT in which plural unit transistors are connected in parallel, “hot-spot” frequently occurs. “Hot-spot” is a phenomenon in which a certain transistor is supplied with a current larger than the other's. This phenomenon derives from the following events. Variation in characteristic or in heat liberation between the plural unit transistors makes a current value of a certain transistor greater than the other's, and the large current increases the operation temperature, which serves as a positive feedback and further increases the current. As a result only a part of the transistors is driven.

The following is one of the methods for preventing the phenomenon. In this method, a series resistor is provided in the emitter of each unit transistor. On an increase in collector current, the resistor increases the emitter potential, and therefore serves as a negative feedback which suppresses the collector current. Such a resistor is called a ballast resistor, which can be made by a thin film resistor in the semiconductor process. In a transistor like a HBT in which the active areas like emitter, base, collector etc. are vertically stacked by epitaxial growth, the ballast resistor is often provided in the emitter as one of the layers. In this case of incorporating the ballast resistor in the completed transistor, it is not necessary to externally provide a circuit element of thin film resistor or the like. On this account the multi-finger type HBT laid out as in Embodiment 1 (FIG. 2) can be securely driven.

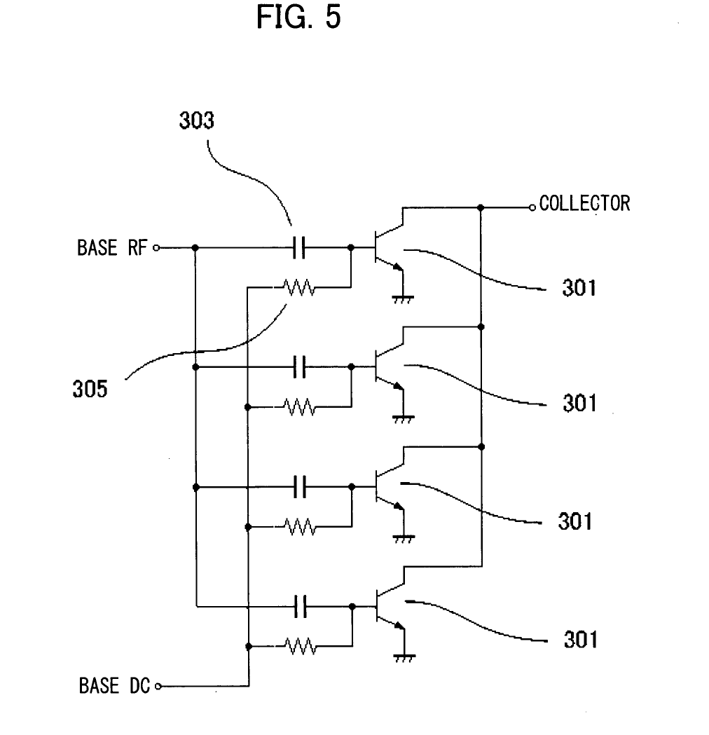

FIG. 5 shows a circuit diagram which is another solution of the foregoing problem. In this example, a series resistor is provided in the base. The circuit diagram of FIG. 5 is a multi-finger type HBT including 4 unit transistors 301. In this structure, a capacitor 303 is provided in series between base RF terminal for supplying RF signals and the base terminal of each unit transistor 301. The capacitor 303 serves to transmit RF signals to the base terminal of each unit transistor with low signal loss, and also isolates the base terminal from DC current flow. On the other hand, a resistor 305 is provided in series between the base DC terminal for supplying base potentials and the base terminal of each unit transistor 301. With the provision of such resistors, the occurrence of “hot-spot” is prevented.

Now assume a case where the collector current of a certain transistor among the unit transistors constituting the multi-finger type HBT increases. Since the base current flows via the resistor 305, the resistor 303 connected to the base of this unit transistor undergoes a larger voltage decrease than the other unit transistors due to the increase in base current which derives from the increase in collector current. This decrease in voltage diminishes the base potential, generating a negative feedback which suppresses the outstanding increase in collector current. Such a resistor is often called a base ballast resistor.

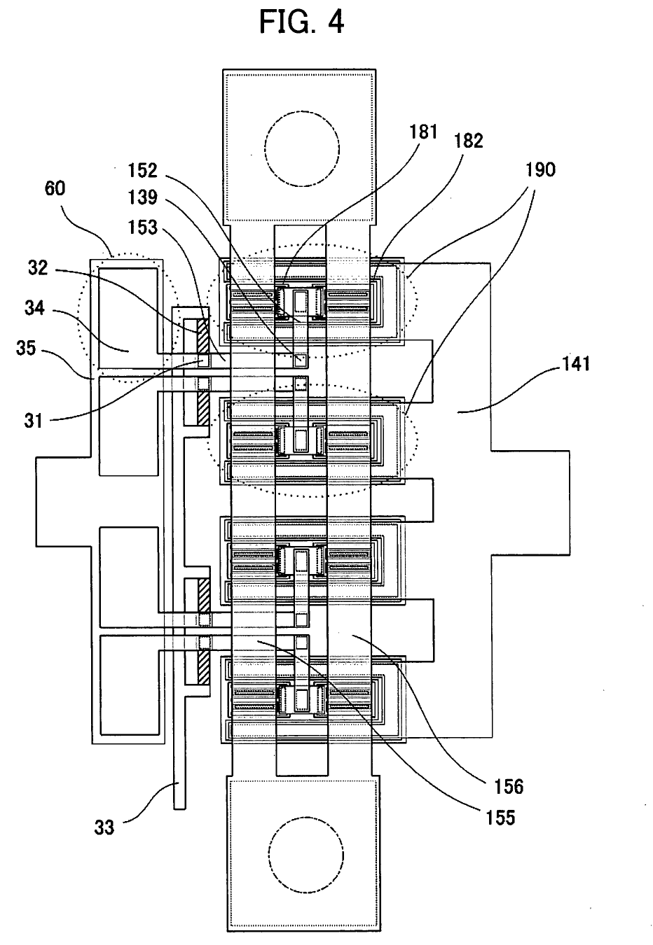

FIG. 4 shows another example of multi-finger type HBT according to the present invention. This multi-finger type HBT includes base ballast resistors. Note that, in this multi-finger type HBT, materials having the equivalent functions as those in FIG. 2 of the first embodiment will be given the same reference symbols, and explanation thereof will be omitted here. In this embodiment, each unit transistor 190 is a HBT constituted of two transistor components 181 and 182 with separate collector layers, as with the first embodiment. Further, the structures of drawing wire section 141 of the collector electrode and the drawing wire sections 155 and 156 of the emitter electrode are also the same as those of the multi-finger type HBT of the first embodiment shown in FIG. 2.

In this example, the base of each unit transistor 190 is connected to a series resistor, and therefore each unit transistor 190 has the drawing wire 152 of the base electrode. The drawing wire 152 of the base electrode is connected via a contact hole 139 to a drawing wire 153, which is formed in the lower layer via an insulative film (not shown), drawn through the layer beneath the drawing wire 155 of the emitter. In the contact hole section 31, the drawn drawing wire 153 is connected via a NiCr thin-film transistor 32 to a wiring metal 33 supplied with a base potential. The NiCr thin-film transistor 32 in each unit transistor 190 serves as a base ballast resistor.

In the contact hole section 31, the drawing wire 153 is further connected via a contact hole to a wiring metal 34 formed in the upper layer via an insulative film (not shown). The wiring metal 34 has an overlapping portion 60 of a predetermined area which is overlaid on a wiring metal 35 formed in the lower layer via an insulative film. The overlapping portion 60 constitutes a capacitor of MIM (Metal Insulator Metal) structure. An RF signal supplied from the connecting section beneath the wiring metal 35 is transmitted to the base of each unit transistor constituting the multi-finger type HBT, through the MIM capacitor.

With the foregoing structure, a multi-finger type HBT including base ballast resistors is realized with the HBTs of the present invention. Note that, in the embodiment shown in FIG. 4, the wiring metal 35 in the lower layer constituting the MIM capacitor is provided as a single component serving as a common electrode for the MIM capacitors of all unit transistors. The wiring metal 35 is however not limited to this arrangement, and may be divided depending on the desired layout. For example, an individual electrode for a MIM capacitor for each unit transistor may be provided.

The multi-finger type HBT according to the present embodiment including base ballast resistors is made up of unit HBTs, each of which includes a plurality of transistor components with separate collector layers on a single sub-collector layer, and these transistor components are aligned in the finger direction. With this structure, the emitter area for each unit finger becomes greater without increasing the effective emitter length, providing an effect of preventing characteristic deterioration to a certain extent. An excessive increase in size of finger alignment direction is also prevented. Further, due to the effect given by the base ballast resistors, “hot-spot” is prevented even in the large current area, and the operation becomes stable. Consequently, a high-output and high-frequency transistor is realized with superior performance.

### Fourth Embodiment

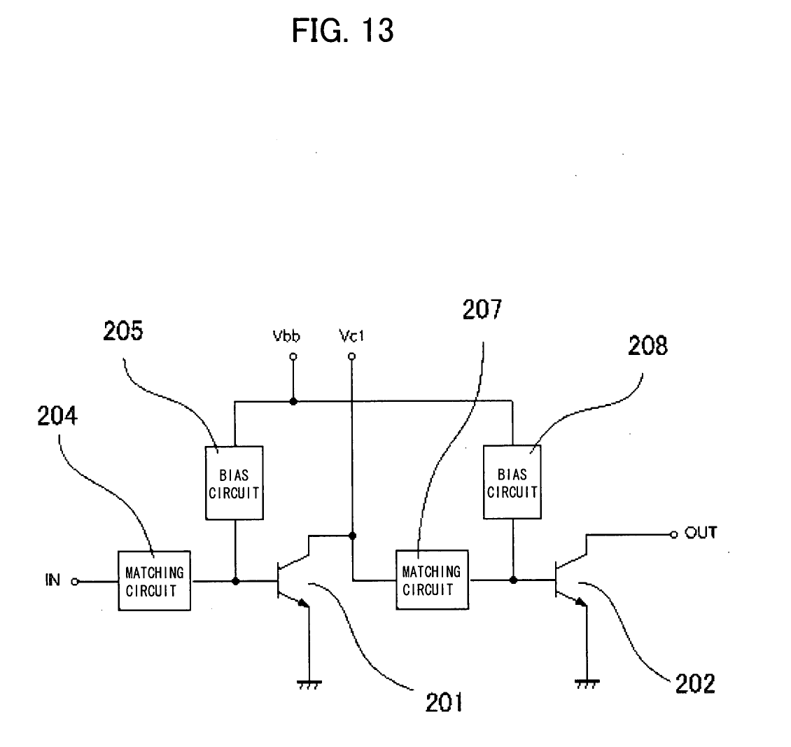

The HBT according to the present embodiment can be used as the amplification HBT 201 or 202 in a transmission power amplifier MMIC shown in FIG. 13, which is explained in the section of “Background Art”. Particularly, the multi-finger type HBT constituted of HBTs according to the present embodiment is useful for an output-stage HBT 202. With the effect of the layout in which a multi-finger type HBT is realized with a small area while ensuring a sufficient emitter area for coping with large output power, it is not necessary to increase the chip size of amplifier MMIC.

### SUMMARY OF EMBODIMENTS

According to the described embodiments, the present invention provides a HBT layout which ensures a large emitter area without a significant increase in effective emitter length which affects characteristic deterioration. Consequently, a desired characteristic is ensured without decreasing output power for each emitter area in a unit transistor. By constituting a unit transistor with the HBT according to the present embodiment, it is possible to provide a multi-finger type HBT capable of large output without increasing the number of fingers. Further, the increase in emitter area does not cause a significant increase in unit transistor width, and therefore the multi-finger type HBT can be laid out in a small area.

A multi-finger type heterojunction bipolar transistor according to the present invention is constituted of a plurality of unit transistors, which are the foregoing heterojunction bipolar transistors comprising a plurality of transistor components. The unit transistors are parallely arranged in a line.

A multi-finger type heterojunction bipolar transistor according to the present invention is constituted of a plurality of unit transistors, which are the foregoing heterojunction bipolar transistors comprising a plurality of transistor components. The unit transistors are parallely arranged in a line in a longitudinal direction of an emitter.

With this arrangement, the emitter area of unit transistor can be enlarged without deteriorating the characteristic of transistor. On this account, a multi-finger type heterojunction bipolar transistor with a large emitter area can be realized without increasing the finger number. Since the increase in emitter area of unit transistor does not cause a significant change in transistor width, the size of multi-finger type heterojunction bipolar transistor in the width direction does not increase significantly, either.

A power amplifier according to the present embodiment includes an amplification element realized by the foregoing heterojunction bipolar transistor including a plurality of transistor components.

A power amplifier according to the present embodiment includes an amplification element realized by the foregoing multi-finger type heterojunction bipolar transistor.

This arrangement allows layout of an amplification element with a large emitter area in a small area, thereby preventing an increase in chip size of power amplifier capable of large output.

A heterojunction bipolar transistor according to the present embodiment comprises on a sub-collector layer a plurality of transistor components, each of which includes a collector layer, a base layer and an emitter layer, the collector layers being connected one another in parallel, the base layers being connected one another in parallel, and the emitter layers being connected one another in parallel within said transistor components, said emitter layer being a rectangle, said transistor components being arranged in a line in a longitudinal direction of said emitter layer.

A multi-finger type heterojunction bipolar transistor according to the present embodiment is constituted of a plurality of heterojunction bipolar transistors aligned in parallel, each of said heterojunction bipolar transistors comprising on a sub-collector layer a plurality of transistor components, each of which includes a collector layer, a base layer and an emitter layer, the collector layers being connected one another in parallel, the base layers being connected one another in parallel, and the emitter layers being connected one another in parallel within said transistor components, said emitter layer being a rectangle, said transistor components being arranged in a line in a longitudinal direction of said emitter layer.

A multi-finger type heterojunction bipolar transistor according to the present embodiment is constituted of a plurality of heterojunction bipolar transistors aligned in parallel in a short-length direction of the emitter, said heterojunction bipolar transistor comprising on a sub-collector layer a plurality of transistor components, each of which includes a collector layer, a base layer and an emitter layer, the collector layers being connected one another in parallel, the base layers being connected one another in parallel, and the emitter layers being connected one another in parallel within said transistor components, said emitter layer being a rectangle, said transistor components being arranged in a line in a longitudinal direction of said emitter layer.

A power amplifier according to the present embodiment comprises a heterojunction bipolar transistor as an amplification element, said heterojunction bipolar transistor comprising on a sub-collector layer a plurality of transistor components, each of which includes a collector layer, a base layer and an emitter layer, the collector layers being connected one another in parallel, the base layers being connected one another in parallel, and the emitter layers being connected one another in parallel within said transistor components, said emitter layer being a rectangle, said transistor components being arranged in a line in a longitudinal direction of said emitter layer.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, * provided such variations do not exceed the scope of the patent claims set forth below.

What is claimed is:

1. A heterojunction bipolar transistor comprising a plurality of transistor components on a sub-collector layer, collector layers of said transistor components being separated one another, said transistor components being arranged in a line in a longitudinal direction of an emitter.

2. A multi-finger type heterojunction bipolar transistor constituted of a plurality of heterojunction bipolar transistors aligned in parallel, each of said heterojunction bipolar transistors comprising a plurality of transistor components on a sub-collector layer, collector layers of said transistor components being separated one another, said transistor components being arranged in a line in a longitudinal direction of an emitter.

3. A multi-finger type heterojunction bipolar transistor constituted of a plurality of heterojunction bipolar transistors aligned in parallel in a short-length direction of an emitter, said heterojunction bipolar transistor comprising a plurality of transistor components on a sub-collector layer, collector layers of said transistor components being separated one another, said transistor components being arranged in a line in a longitudinal direction of the emitter.

4. A power amplifier comprising a heterojunction bipolar transistor as an amplification element, said heterojunction bipolar transistor comprising a plurality of transistor components on a sub-collector layer, collector layers of said transistor components being separated one another, said transistor components being arranged in a line in a longitudinal direction of an emitter.

5. A heterojunction bipolar transistor comprising on a sub-collector layer a plurality of transistor components, each of which includes a collector layer, a base layer and an emitter layer, the collector layers being connected one another in parallel, the base layers being connected one another in parallel, and the emitter layers being connected one another in parallel within said transistor components, said emitter layer being a rectangle, said transistor components being arranged in a line in a longitudinal direction of said emitter layer.

6. A multi-finger type heterojunction bipolar transistor constituted of a plurality of heterojunction bipolar transistors aligned in parallel, each of said heterojunction bipolar transistors comprising on a sub-collector layer a plurality of transistor components, each of which includes a collector layer, a base layer and an emitter layer, the collector layers being connected one another in parallel, the base layers being connected one another in parallel, and the emitter layers being connected one another in parallel within said transistor components, said emitter layer being a rectangle, said transistor components being arranged in a line in a longitudinal direction of said emitter layer.

7. A multi-finger type heterojunction bipolar transistor constituted of a plurality of heterojunction bipolar transistors aligned in parallel in a short-length direction of an emitter layer, said heterojunction bipolar transistor comprising on a sub-collector layer a plurality of transistor components, each of which includes a collector layer, a base layer and an emitter layer, the collector layers being connected one another in parallel, the base layers being connected one another in parallel, and the emitter layers being connected one another in parallel within said transistor components, said emitter layer being a rectangle, said transistor components being arranged in a line in a longitudinal direction of said emitter layer.

8. A power amplifier comprising a heterojunction bipolar transistor as an amplification element, said heterojunction bipolar transistor comprising on a sub-collector layer a plurality of transistor components, each of which includes a collector layer, a base layer and an emitter layer, the collector layers being connected one another in parallel, the base layers being connected one another in parallel, and the emitter layers being connected one another in parallel within said transistor components, said emitter layer being a rectangle, said transistor components being arranged in a line in a longitudinal direction of said emitter layer.
